(19) United States
(12) Patent Application Publication
(10) Pub. No.: US 2004/0070942 A1
(43) Pub. Date: Apr. 15, 2004

(54) Electronic apparatus

(75) Inventors: Kentaro Tomioka, Sayama-shi (JP); Katsumi Hisano, Kashiwa-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/635,481

(22) Filed: Aug. 7, 2003

(30) Foreign Application Priority Data
Aug. 30, 2002 (JP) 2002-255545

(51) Int. Cl. H05K 7/20

(52) U.S. Cl. 361/700; 361/687; 165/80.3; 62/259.2; 174/15.2

(57) ABSTRACT

An electronic apparatus comprises a heat-generating component therein, a heat receiving portion thermally connected to the heat-generating component, a heat radiating portion to radiate heat generated by the heat-generating component, and a circulation pipe to circulate a liquid coolant between the heat receiving portion and the heat radiating portion. A part of the circulation pipe has pipes different from the other part in inside diameter.

### CROSS-REFERENCE TO RELATED APPLICATIONS

This application is based upon and claims the benefit of priority from the prior Japanese Patent Application No. 2002-255545, filed Aug. 30, 2002, the entire contents of which are incorporated herein by reference.

### BACKGROUND OF THE INVENTION

1. Field of the Invention

The present invention relates to an electronic apparatus having therein a heat-generating component, such as a semiconductor package, and more particularly, to an electronic apparatus having a cooling structure for enhancing the cooling performance of the heat-generating component.

2. Description of the Related Art

Portable electronic apparatuses, such as notebook-type portable computers and mobile communications equipment, are provided with microprocessors for processing multimedia information. Higher processing speeds and the development of highly multifunctional versions of the microprocessors of this type have entailed a rapid increase in the heat release amount during operation. In order to ensure stable operation of the microprocessors, therefore, the heat radiating capability of the microprocessors must be enhanced.

To cope with this, a conventional electronic apparatus is furnished with an air-cooling device for forced cooling of the microprocessor. The cooling device comprises a heat sink that absorbs heat from the microprocessor and an electric fan that blows cool air over the heat sink.

The heat sink has a heat receiving portion that receives heat from the microprocessor, a plurality of radiating fins, and an air passage. The air passage is defined extending along the heat receiving portion and the radiating fins. An electric fan blows air through the air passage. The air compulsorily cools the heat sink as it flows between the radiating fins. Thus, the heat from the microprocessor transmitted to the heat sink is removed by the flow of air and discharged to the outside of the electronic apparatus through the downstream end of the passage.

According to this conventional cooling system, the air that flows through the air passage serves as a cooling medium that removes heat from the microprocessor. Thus, the cooling performance of the microprocessor substantially depends on the amount of airflow, and the area of contact between the airflow and the heat sink.

If the airflow is increased to improve the cooling performance of the microprocessor, however, the rotational speed of the electric fan must be increased, so that substantial noise is produced inevitably. If the radiating fins are increased in number or in size, moreover, the heat sink becomes bulky and requires a wide installation space in the electronic apparatus. Therefore, this configuration cannot be applied to small-sized electronic apparatuses, such as portable computers.

Microprocessors for electronic apparatuses are expected to be further speeded up and given more functions in the near future. Accordingly, the amount of heat released from the microprocessors is expected to increase drastically. Presumably, therefore, such microprocessors cannot be sufficiently cooled by conventional forced air-cooling systems.

To solve this problem, a so-called liquid-cooling system is described in Jpn. Pat. Appln. KOKAI Publication No. 7-142886, for example. In this system, a liquid that is much higher than air in specific heat is used as a coolant to enhance the ability to cool efficiency the microprocessor.

According to this novel cooling system, a heat receiving head is set in a casing that contains the microprocessor, and a radiating header is set in a display unit that is supported on the casing. The heat receiving head is thermally connected to the microprocessor. A passage through which a liquid coolant flows is defined in the heat receiving head.

The radiating header is thermally connected to the display unit, and a passage through which the liquid coolant flows is also defined in the radiating header. The respective passages of the heat receiving head and the radiating header are connected to each other by a circulation path through which the coolant is circulated.

According to this cooling system, heat from the microprocessor is transmitted form the heat receiving head to the coolant and then transferred to the radiating header as the coolant flows. The heat transferred to the radiating header is diffused by thermal conduction as the coolant flows through the passage, and is discharged from the radiating header to the atmosphere through the display unit.

Thus, the heat from the microprocessor can be efficiently transferred to the display unit by utilizing the flow of the coolant. In consequence, the cooling performance of the microprocessor can be made higher than in the case of the conventional forced air-cooling, and there is no noise problem.

The cooling system described above may be applied to a notebook-type portable computer, such as the one described in Jpn. Pat. Appln. KOKAI Publication No. 7-143886, as an electronic apparatus. In this case, a display unit is rockably supported on a casing by hinge portions, so that circulation pipes extend between the casing and the display unit through the hinge portions. As the display unit is opened or closed, according to this configuration, the circulation pipes may possibly twist and collapse or touch their surrounding members to be worn or damaged thereby.

If the circulation pipes collapse in this manner, the circulation of the coolant is inhibited, so that the cooling efficiency is lowered, or in the worst case, cooling is difficult. If the circulation pipes are worn or damaged, moreover, the coolant leaks out, so that the cooling capability is ruined inevitably.

### BRIEF SUMMARY OF THE INVENTION

An electronic apparatus according to an embodiment of the invention comprises: a heat-generating component; a heat receiving portion thermally connected to the heat-generating component; a heat radiating portion to radiate heat generated by the heat-generating component; and a circulation pipe to circulate a liquid coolant the heat receiving portion and the heat radiating portion. A part of the circulation pipe has pipes different from the other part in inside diameter.

An electronic apparatus according to another embodiment of the invention comprises: a first casing; a heat-generating component arranged in the first casing; a heat receiving portion located in the first casing and thermally connected to the heat-generating component; a second casing connected to the first casing by a hinge portion; a heat radiating portion to radiate heat generated by the heat-generating component, the heat radiating portion being arranged in the second casing; and a circulation pipe to circulate a liquid coolant the heat receiving portion and the heat radiating portion. The circulation pipe extends through the hinge portion and bestrides the boundary between the first and second casings. A part of the circulation pipe which passes through the hinge portion has pipes different from the other part in inside diameter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer according to a first embodiment of the invention with its display unit in an open position;

FIG. 2 is a perspective view schematically showing the positional relations between a heat receiving head, radiator, circulation path having a centrifugal pump, and electric fan of the portable computer;

FIG. 3 is a sectional view showing the positional relations between the heat receiving head, radiator, circulation path having the centrifugal pump, and electric fan of the portable computer;

FIG. 4 is a sectional view showing the positional relation between a semiconductor package and the heat receiving head of the portable computer;

FIG. 5 is a sectional view showing the heat receiving head connected thermally to the semiconductor package in the portable computer;

FIG. 6 is a sectional view showing the positional relation between the electronic fan and suction ports of a second casing of the portable computer;

FIG. 7 is a sectional view showing the configuration of fins of the portable computer;

FIG. 8 is a sectional view showing the configuration of the radiator of the portable computer;

FIG. 9 is a sectional view showing the configuration of an odd-shaped portion of the circulation path for a coolant of the portable computer;

FIG. 10 is a perspective view showing the odd-shaped portion;

FIG. 11 is a perspective view showing the configuration of an odd-shaped portion according to a second embodiment of the invention;

FIG. 12 is a sectional view of the odd-shaped portion taken along line XII-XII of FIG. 11;

FIG. 13 is a perspective view showing the configuration of an odd-shaped portion according to a third embodiment of the invention; and

FIG. 14 is a perspective view showing the configuration of an odd-shaped portion according to a fourth embodiment of the invention.

### DETAILED DESCRIPTION OF THE INVENTION

Portable computers as electronic apparatuses according to embodiments of the present invention will now be described with reference to the accompanying drawings.

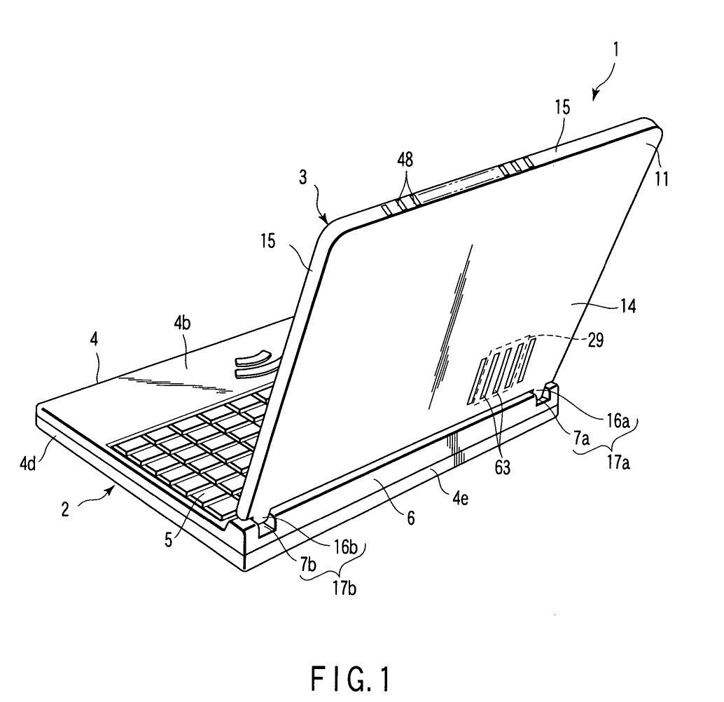

As shown in FIGS. 1 to 3, a portable computer 1 according to a first embodiment comprises an apparatus body 2 and a display unit 3. The body 2 includes a first casing 4 in the form of a flat box. The first casing 4 has a bottom wall 4a, top wall 4b, front wall 4c, left- and right-hand sidewalls 4d, and rear wall 4e. The top wall 4b is provided with a keyboard 5. The top wall 4b has a display support portion 6 behind the keyboard 5. The display support portion 6 projects upward from the rear end portion of the top wall 4b and extends in the width direction of the first casing 4. The support portion 6 has a pair of recesses 7a and 7b, which are spaced in the width direction of the first casing 4.

The display unit 3 is provided with a liquid crystal display panel 10 and a second casing 11 in the form of a flat box. The display panel 10 has a screen 10a on its front face that displays images. The second casing 11 has a front wall 13, in which an opening 12 is formed, a rear wall 14, and four sidewalls 15. The rear wall 14 is opposed to the front wall 13 and the opening 12. The front wall 13, rear wall 14, and sidewalls 15 surround the display panel 10. The screen 10a of the display panel 10 is exposed to the outside of the second casing 11 through the opening 12. The first and second casings 4 and 11 constitute a casing according to the present invention.

The second casing 11 has a pair of legs 16a and 16b that protrude from its one end portion. The legs 16a and 16b are hollow and spaced in the width direction of the second casing 11. The legs 16a and 16b are fitted in the recesses 7a and 7b, respectively, of the first casing 4, and are connected to the first casing 4 by means of a hinge unit (not shown), thereby forming hinge portions 17a and 17b. The display unit 3 is supported on the apparatus body 2 and rockable between a closed position where it is leveled to overlie the keyboard 5 and an open position where it rises to expose the keyboard 5 and the screen 10a.

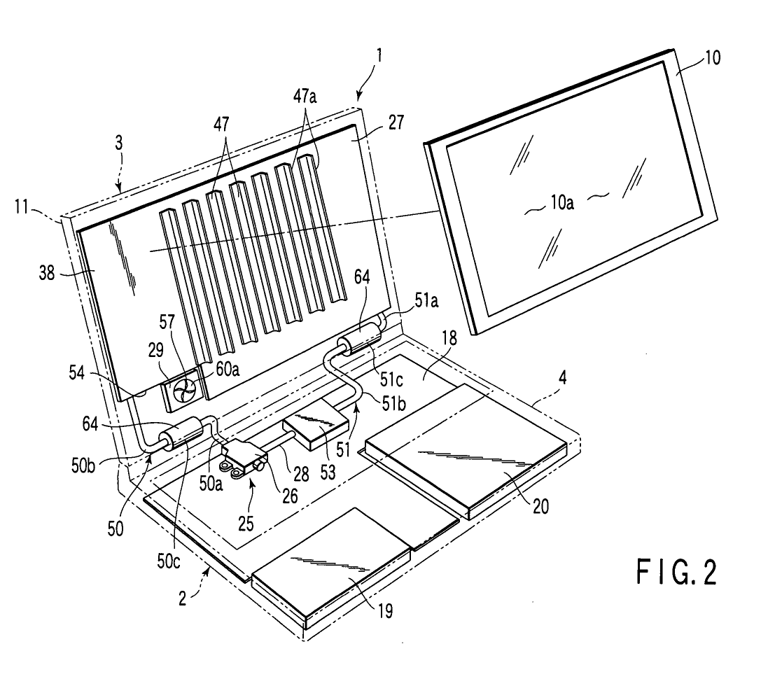

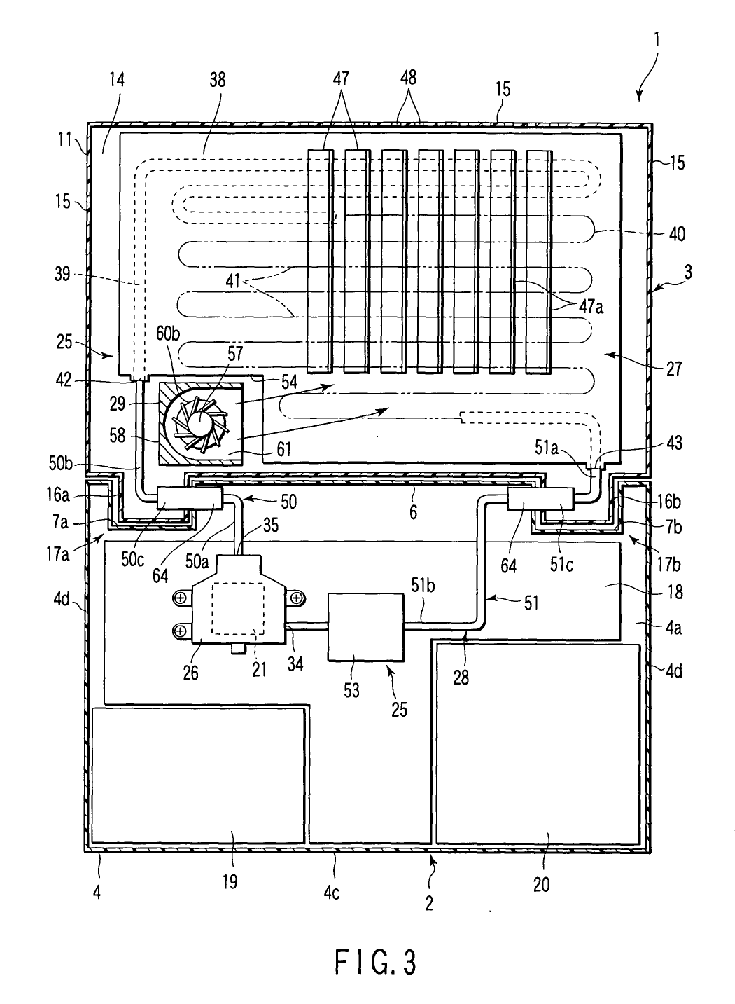

As shown in FIGS. 2 and 3, the first casing 4 contains printed wiring board 18, a hard disc drive unit 19 for use as a packed device, and a CD-ROM drive unit 20. The wiring board 18 and the drive units 19 and 20 are arranged side by side on the bottom wall 4a of the first casing 4.

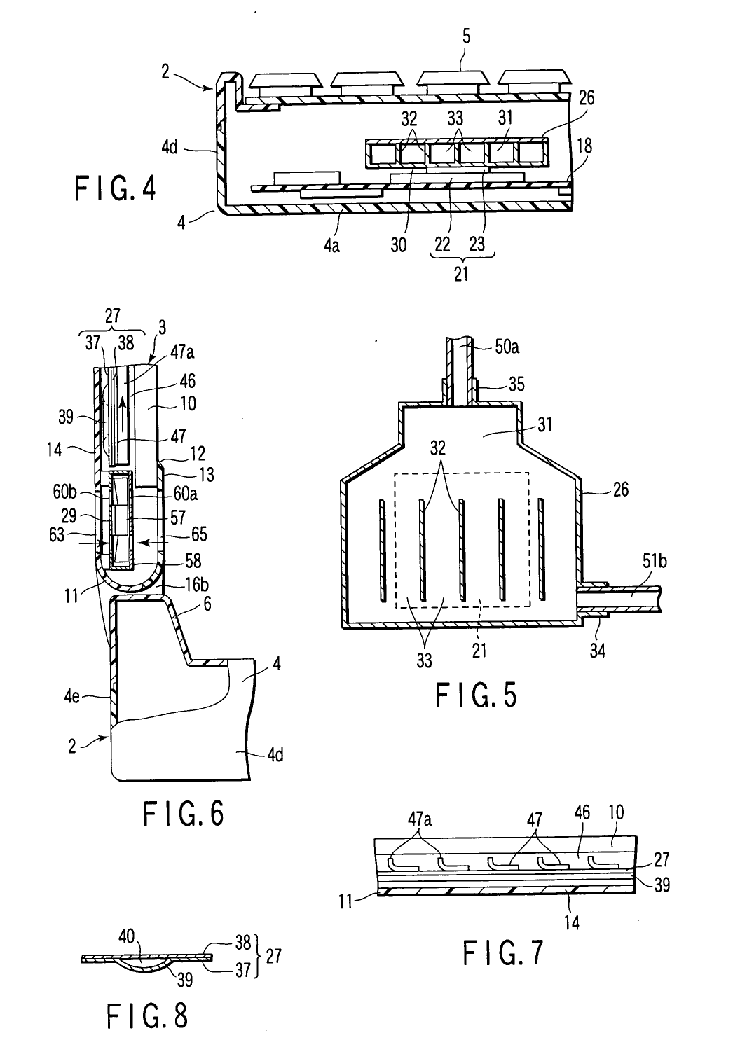

As shown in FIG. 4, a semiconductor package 21 for use as a heat-generating component is mounted on the upper surface of the printed wiring board 18. The package 21 constitutes a microprocessor that serves as the center of the portable computer 1, and is situated corresponding to the rear part of the printed board 18. The package 21 has a base substrate 22 and an IC chip 23 that is located in the central portion of the upper surface of the substrate 22. Owing to its increased processing speed and multifunctional performance, the IC chip 23 generates a large amount of heat during operation. Thus, maintenance of its stable operation requires cooling.

As shown in FIGS. 2 and 3, the portable computer 1 is mounted with a liquid-cooling unit 25 for cooling the semiconductor package 21. The cooling unit 25 is provided with a heat receiving head 26 that serves as a heat receiving portion, a radiator 27 that serves as a heat radiating portion, a circulation path 28, an electric fan 29, and a centrifugal pump 53.

The heat receiving head 26 is located in the first casing 4. As shown in FIGS. 4 and 5, the head 26 is a flat box that is fixed to the upper surface of the printed wiring board 18 by means of screws. The head 26 has a plane configuration a size larger than that of the semiconductor package 21. The lower surface of the heat receiving head 26 forms a flat heat receiving surface 30. The surface 30 is connected thermally to the IC chip 23 of the package 21 by means of thermally conductive grease or sheet (not shown).

A coolant passage 31 is defined in the heat receiving head 26. The passage 31 is thermally connected to the IC chip 23 by the heat receiving surface 30, and is divided into a plurality of sections 33. The head 26 has a coolant inlet 34 and a coolant outlet 35. The inlet 34 is situated at the upstream end of the passage 31, and the outlet 35 at the downstream end.

As shown in FIGS. 2, 3 and 6, the radiator 27 is set in the second casing 11 and interposed between the rear wall 14 of the casing 11 and the liquid crystal display panel 10. The radiator 27 is in the form of an oblong plate that is substantially equal to the rear wall 14 in size. As shown in FIG. 8, the radiator 27 is provided with first and second radiating plates 37 and 38. The first and second radiating plates 37 and 38 are superposed on each other and joined by contact bonding.

The first radiating plate 37 has a bulge 39 that projects on the side opposite from the second radiating plate 38. The bulge 39 extends in a meandering fashion substantially over the whole surface of the first radiating plate 37 and opens to the joint surface of the second radiating plate 38. The plate 38 closes an open end of the bulge 39. Thus, the bulge 39 defines a coolant passage 40 over the second radiating plate 38. The coolant passage 40 has a plurality of straight pipe portions 41 that extend in the width direction of the second casing 11. The pipe portions 41 are spaced in the height direction of the second casing 11 in a parallel relationship.

The radiator 27 has a coolant inlet 42 and a coolant outlet 43. The inlet 42 is continuous with the upstream end of the coolant passage 40. The inlet 42 is situated on the left-hand end portion of the radiator 27 and adjoins the left-hand leg 16a of the second casing 11. The outlet 43 is continuous with the downstream end of the passage 40. The outlet 43 is situated on the right-hand end portion of the radiator 27 and adjoins the right-hand leg 16b of the second casing 11. Thus, the inlet 42 and the outlet 43 are spaced in the width direction of the second casing 11.

The first radiating plate 37 that has the bulge 39 faces the rear wall 14 of the second casing 11. A narrow gap is defined between the bulge 39 and the rear wall 14.

The second radiating plate 38 of the radiator 27 faces the liquid crystal display panel 10. An air passage 46 is defined between the plate 38 and the panel 10. The plate 38 is fitted with a plurality of radiating fins 47. Each fin 47 is formed of an aluminum plate separate from the plate 38 and is exposed to the passage 46. Each fin 47 has a raised portion 47a raised from its one side edge at right angles to it. The fins 47 are bonded and thermally connected to the second radiating plate 38. They extend in the height direction of the display unit 3 and are spaced in the width direction of the display unit 3 in a parallel relationship.

The air passage 46 and the fins 47 extend vertically along the display unit 3 when the unit 3 is in the open position. In this state, the respective upper ends of the fins 47 face one of the sidewalls 15 that is situated at the upper end of the second casing 11. As shown in FIGS. 1, 3 and 6, the one sidewall 15 has a plurality of exhaust vents 48. The vents 48 are situated at the upper end of the air passage 46 as long as the display unit 3 is in the open position.

The electric fan 29 serves to blow the cool air compulsorily to the radiator 27 and is located in the second casing 11. The fan 29 is set in a notch 54 of the radiator 27. The fan 29 is provided with a centrifugal impeller 57 and a fan casing 58 that holds the impeller 57. The impeller 57 is driven by a motor (not shown) when a predetermined value is reached by the temperature of the semiconductor package 21, for example. The fan casing 58 is a flat box that is sandwiched between the front and rear walls 13 and 14 of the second casing 11.

The fan casing 58 has first and second suction ports 60a and 60b and a discharge port 61. The suction ports 60a and 60b are arranged coaxially with the impeller 57 between them. The first suction port 60a faces a plurality of first intake vents 65 in the front wall 13. The second suction port 60b faces a plurality of second intake vents 63 in the rear wall 14. The discharge port 61 opens so as to be directed to the right-hand side of the interior of the second casing 11.

The electric fan 29 is situated at the lower end portion of the radiator 27 when the display unit 3 is rocked to the open position. Thus, the discharge port 61 of the fan casing 58 is situated below the respective lower ends of fins 47 as long as the display unit 3 is in the open position.

As shown in FIGS. 2 and 3, the circulation path 28 of the cooling unit 25 is provided with first and second circulation pipes 50 and 51. The pipes 50 and 51 span the boundary between the first and second casings 4 and 11.

The first circulation pipe 50 passes through the one hinge portion 17a and connects the coolant outlet 35 of the heat receiving head 26 and the coolant inlet 42 of the radiator 27. The pipe 50 includes an upstream portion 50a, downstream portion 50b, and odd-shaped portion 50c. The upstream portion 50a of the pipe 50 is connected to the coolant outlet 35 of the heat receiving head 26 and held in the first casing 4. The downstream portion 50b of the pipe 50 is connected to the coolant inlet 42 of the radiator 27 and held in the left-hand end portion of the second casing 11. The odd-shaped portion 50c connects the upstream and downstream portions 50a and 50b. The odd-shaped portion 50c penetrates the recess 7a and the leg 16a in the hinge portion 17a and is situated on the axis of rotation of the display unit 3.

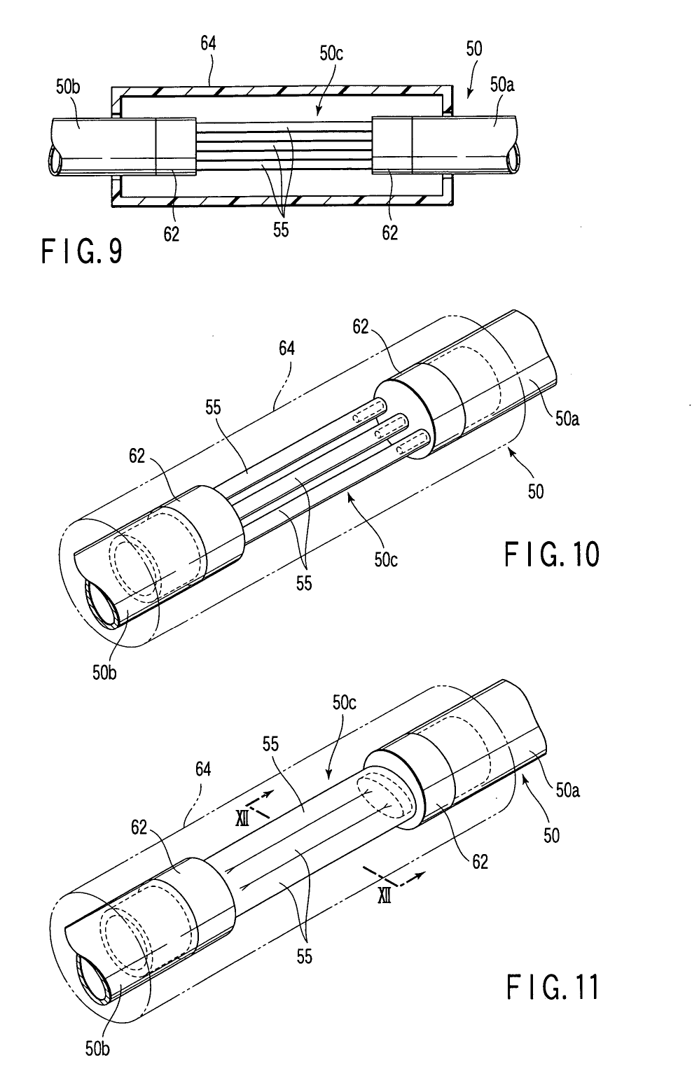

As shown in FIGS. 3, 9 and 10, the upstream and downstream portions 50a and 50b of the first circulation pipe 50 are formed of circulation pipes of, e.g., aluminum or another metal having the same diameter. The odd-shaped portion 50c, which is connected between the upstream and downstream portions 50a and 50b, has three odd-shaped circulation pipes 55, for example. The pipes 55 have inside and outside diameters smaller than those of the circulation pipes that constitute the upstream and downstream portions 50a and 50b. The pipes 55 are arranged in parallel with one another, and their respective opposite ends are connected to the upstream and downstream portions 50a and 50b by means of pipe joints 62, individually.

The odd-shaped circulation pipes 55 are formed of a material different from the material of the other circulation pipes. In this case, the pipes 55 are formed of elastic flexible tubes, such as butyl tubes, silicone tubes, or Teflon (trademark) tubes. The upstream and downstream portions 50a and 50b of the first circulation pipe 50 may be formed of the same material with the odd-shaped circulation pipes 55 in place of metal.

The odd-shaped portion 50c of the first circulation pipe 50 is covered by a cylindrical protective cover 64 that is formed of plastics, for example. The cover 64 has a diameter larger than that of the upstream and downstream portions 50a and 50b. It is fixed to a casing, e.g., the first casing 4, and penetrates the recess 7a and the leg 16a of the hinge portion 17a.

The second circulation pipe 51 passes through the other hinge portion 17b and connects the coolant outlet 43 of the radiator 27 and the coolant inlet 34 of the heat receiving head 26. The pipe 51 includes an upstream portion 51a, downstream portion 51b, and odd-shaped portion 51c. The upstream portion 51a of the pipe 51 is connected to the coolant outlet 43 of the radiator 27 and held in the right-hand end portion of the second casing 11. The downstream portion 51b of the pipe 51 is connected to the coolant inlet 34 of the heat receiving head 26 and held in the first casing 4. The odd-shaped portion 51c connects the upstream and downstream portions 51a and 51b. The odd-shaped portion 51c penetrates the recess 7b and the leg 16b in the hinge portion 17b and is situated on the axis of rotation of the display unit 3.

The upstream and downstream portions 51a and 51b and the odd-shaped portion 51c of the second circulation pipe 51 are constructed in the same manner as their respective counterparts 50a, 50b and 50c of the first circulation pipe 50. More specifically, the upstream and downstream portions 51a and 51b are formed of circulation pipes of, e.g., aluminum or another metal having the same diameter. The odd-shaped portion 51c has three odd-shaped circulation pipes 55, for example, which have inside and outside diameters smaller than those of the circulation pipes that constitute the upstream and downstream portions 51a and 51b. The pipes 55 are arranged in parallel with one another, and their respective opposite ends are connected to the upstream and downstream portions 51a and 51b by means of pipe joints 62, individually. The odd-shaped portion 51c is covered by another protective cover 64.

In the cooling unit 25 described above, a liquid coolant, e.g., a liquid coolant, is sealed in the coolant passage 31 of the heat receiving head 26, the coolant passage 40 of the radiator 27, and the circulation path 28. The coolant may, for example, be an antifreeze solution that is formed of water doped with ethylene glycol and a corrosion inhibitor, if necessary.

As shown in FIGS. 2 and 3, the circulation path 28 includes a small-sized centrifugal pump 53 as circulating means, for example. The pump 53 is used to force circulate the coolant between the heat receiving head 26 and the radiator 27. The pump 53 is connected to the middle portion of the downstream portion 51b of the second circulation pipe 51 and is located in the first casing 4. The centrifugal pump 53 is activated when it is connected to the power supply or when the semiconductor package 21 is heated to a predetermined temperature, for example.

In the portable computer 1 constructed in this manner, the IC chip 23 of the semiconductor package 21 generates heat during the operation of the computer. The heat from the chip 23 is transmitted to the heat receiving surface 30 of the heat receiving head 26. Since the head 26 has the coolant passage 31 in which the coolant is sealed, the coolant absorbs much of the heat transmitted to the surface 30.

When the temperature of the semiconductor package 21 reaches a given value, the centrifugal pump 53 starts to operate. Thereupon, the coolant is forced out from the heat receiving head 26 toward the radiator 27 and force circulated between the coolant passage 31 of the head 26 and the coolant passage 40 of the radiator 27.

Thus, the coolant heated by heat exchange in the heat receiving head 26 is pressurized by means of the centrifugal pump 53 and guided into the radiator 27 through the first circulation pipe 50. The coolant flows from the coolant inlet 42 toward the coolant outlet 43 through the long meandering coolant passage 40. The heat from the IC chip 23 that is absorbed by the coolant in the process of this flow is diffused into the first and second radiating plates 37 and 38 and discharged from the surface of the radiator 27 into the second casing 11.

Some of the heat diffused into the radiator 27 is transmitted from the second radiating plate 38 to the fins 47 and discharged from the respective surfaces of the fins 47 into the air passage 46. In consequence, the heated coolant is cooled by heat exchange in the radiator 27.

When the temperature of the semiconductor package 21 reaches a given value, the electric fan 29 starts to operate. When the impeller 57 of the fan 29 rotates, air outside the display unit 3 is sucked into the suction ports 60a and 60b of the fan casing 58 through the intake vents 65 and 63 of the second casing 11, as indicated by arrows in FIG. 6. The sucked air is discharged from the outer peripheral portion of the impeller 57 and delivered toward the radiator 27 through the discharge port 61 of the fan casing 58.

Thereupon, a flow of the air is formed in the second casing 11. This air flows upward through the air passage 46, as indicated by arrow in FIG. 6, and force cools the radiator 27 as it passes between the fins 47. Thus, the heat from the IC chip 23 transmitted to the radiator 27 is removed by the flow of the air. The air warmed by heat exchange with the radiator 27 is discharged from the display unit 3 through the exhaust vents 48 at the upper end of the second casing 11.

The coolant that is cooled as it passes through the radiator 27 is returned to the coolant passage 31 of the heat receiving head 26 through the second circulation pipe 51. After the coolant absorbs the heat from the IC chip 23 again as it flows through the passage 31, it is guided to the radiator 27. As this cycle is repeated, the heat form the IC chip 23 is discharged to the outside of the portable computer 1 through the display unit 3.

According to this configuration, the radiator 27 is set in the second casing 11 of the display unit 3, and the liquid coolant is circulated between the radiator 27 and the heat receiving head 26 that receives heat from the semiconductor package 21. Therefore, the heat from the package 21 can be efficiently transferred to the display unit 3 by utilizing the coolant flow and then discharged into the atmosphere. Thus, the heat radiation performance of the semiconductor package 21 can be enhanced considerably as compared with the case of conventional forced air-cooling.

According to the embodiment described above, those parts of the circulation pipes of the cooling unit 25 which pass through the movable parts or the hinge portions 17a and 17b of the portable computer 1 are constructed as the odd-shaped portions 50c and 51c. Each of the odd-shaped portions 50c and 51c is formed by arranging the odd-shaped circulation pipes 55, which have outside and inside diameters smaller than those of the other circulation pipes, in parallel with one another. In the present embodiment, moreover, the circulation pipes 55 are flexible tubes that are formed of an elastic material. If the odd-shaped portions 50c and 51c of the circulation pipes twist as the display unit 3 is opened or closed, therefore, the circulation pipes can be prevented from collapsing, so that reliable circulation of the coolant can be secured.

Thus, the odd-shaped circulation pipes 55, having small inside and outside diameters, enjoy a thickness-to-diameter ratio higher than those of any other large-diameter circulation pipes, so their strength is improved. Therefore, the collapse of the pipes that is attributable to torsion can be reduced. Owing to their small diameters, the odd-shaped circulation pipes 55 can be easily passed through the hinge portions 17a and 17b and cannot easily touch their surrounding members. In consequence, the pipes 55 can be prevented from being worn or damaged, so that leakage of the coolant can be prevented. Since the protective cover 64 covers the odd-shaped portions 50c and 51c, moreover, the pipes 55 can be more securely prevented from being worn or damaged. If their diameters are reduced, furthermore, the odd-shaped circulation pipes 55 are arranged parallel to one another and connected to the other circulation pipes. In this way, lowering of the flow rate of the coolant and increase of the flow resistance can be prevented, so that smooth circulation of the coolant can be maintained.

For these reasons, the circulation pipes can be prevented from being collapsed or damaged to ensure reliable cooling capability even if the circulation pipes of the cooling unit 25 are arranged penetrating the movable parts of the portable computer 1.

The present invention is not limited to the first embodiment described above, and various changes and modifications may be effected therein without departing from the scope or spirit of the invention. Although the odd-shaped portions of the circulation pipes that constitute the circulation path 28 are located penetrating the hinge portions of the portable computer 1 as the movable parts, they may alternatively be located in any other movable parts. The odd-shaped portions of the circulation pipes need not always be confined to the movable parts, and may alternatively be located in curved or bent parts with substantial curvature. In this case, collapsing the circulation pipes can be also restrained to ensure smooth circulation of the coolant.

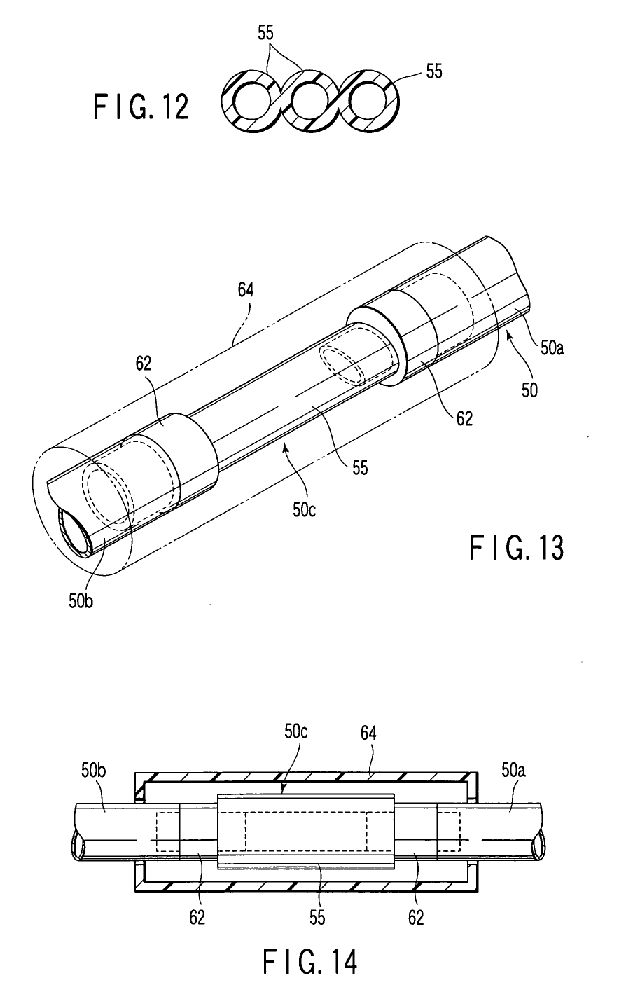

According to a second embodiment shown in FIGS. 11 and 12, an odd-shaped portion 50c of a first circulation pipe 50 of a cooling unit has three odd-shaped circulation pipes 55, for example. The pipes 55 are molded integrally with and extend parallel to one another. An odd-shaped portion 51c of a second circulation pipe 51 is constructed in the same manner as the odd-shaped portion 50c. This configuration can produce the same effects as the first embodiment. Since the odd-shaped circulation pipes 55 are molded integrally with one another, the whole odd-shaped portions have enhanced strength, so that they cannot be easily collapsed and can be assembled with ease.

According to a third embodiment shown in FIG. 13, an odd-shaped portion 50c of a first circulation pipe 50 of a cooling unit is formed of an odd-shaped circulation pipe 55 that has a cross section different from that of circulation pipes that constitute upstream and downstream portions 50a and 50b. While the pipes that constitute the portions 50a and 50b have a circular cross section, the circulation pipe 55 has an elliptic cross section. The major axis of the elliptic section is substantially equal to the diameter of the upstream and downstream portions, and the minor axis smaller than the diameter of the upstream and downstream portions. An odd-shaped portion 51c of a second circulation pipe 51 is constructed in the same manner as the odd-shaped portion 50c.

If the odd-shaped circulation pipe 55 is thus formed having the elliptic cross section, it can be easily passed through narrow portions such as hinge portions. Further, the pipe 55 can be improved in strength against torsion and made less liable to collapse.

According to a fourth embodiment shown in FIG. 14, an odd-shaped portion 50c of a first circulation pipe 50 of a cooling unit is composed of an odd-shaped circulation pipe 55 that has an inside diameter larger than that of circulation pipes that constitute upstream and downstream portions 50a and 50b. An odd-shaped portion 51c of a second circulation pipe 51 is constructed in the same manner as the odd-shaped portion 50c.

With use of the odd-shaped circulation pipe 55 having the large inside diameter, a flow passage can be secured to maintain smooth circulation of the coolant even if the circulation pipe twists and collapses in some measure. The odd-shaped circulation pipe 55 may be designed so that its outside diameter is larger than that of other circulation pipes and its inside diameter substantially equal to that of the other circulation pipes. In this case, the wall thickness of the pipe 55 is increased so that the pipe 55 can be improved in strength against torsion and made less liable to collapse.

The second to fourth embodiments share other configurations with the first embodiment. Therefore, like reference numerals are used to designate like portions throughout the drawings, and a detailed description of those portions is omitted.

According to the embodiments described above, the odd-shaped portions and the other circulation pipes are formed separately and connected to one another by means of pipe joints. Alternatively, however, they may be formed integrally of a common material.

The present invention is not limited to a portable computer, but also applicable to any other electronic apparatus. The respective locations of the components that constitute the cooling unit are not limited to the ones described in connection with the foregoing embodiments, and they may be varied as required. For example, the centrifugal pump may be located in the second casing. Further, the radiator, along with the heat receiving portion, may be provided in the first casing in place of the second casing.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic apparatus comprising:
a heat-generating component;
a heat receiving portion thermally connected to the heat-generating component;
a heat radiating portion to radiate heat generated by the heat-generating component; and
a circulation pipe to circulate a liquid coolant between the heat receiving portion and the heat radiating portion, a part of the circulation pipe including pipes different from the other part in inside diameter.

2. An electronic apparatus according to claim 1, wherein said part of the circulation pipe has an odd-shaped circulation pipe having an inside diameter smaller than that of the other part of the circulation pipe.

3. An electronic apparatus according to claim 1, wherein said part of the circulation pipe has a plurality of parallel odd-shaped circulation pipes having inside and outside diameters smaller than that of the other part of the circulation pipe.

4. An electronic apparatus according to claim 1, wherein said part of the circulation pipe has an odd-shaped circulation pipe having an outside diameter larger than that of the other part of the circulation pipe.

5. An electronic apparatus according to claim 1, wherein said part of the circulation pipe is formed of a material different from that of the other part of the circulation pipe and is elastic.

6. An electronic apparatus according to claim 1, which further comprises a protective cover which covers said part of the circulation pipe.

7. An electronic apparatus comprising:
a first casing;
a heat-generating component arranged in the first casing;
a heat receiving portion located in the first casing and thermally connected to the heat-generating component;
a second casing connected to the first casing by a hinge portion;
a heat radiating portion to radiate heat generated by the heat-generating component, the heat radiating portion being located in the second casing and having a coolant passage; and
a circulation pipe to circulate a liquid coolant between the heat receiving portion and the heat radiating portion, the circulation pipe extending through the hinge portion and spans the boundary between the first and second casings, and that part of the circulation pipe which passes through the hinge portion including pipes different from the other part in inside diameter.

8. An electronic apparatus according to claim 7, wherein the second casing is supported on the first casing by a pair of hinge portions, and the circulation pipe includes a first circulation pipe extending from the heat receiving portion to the heat radiating portion through one of the hinge portions and a second circulation pipe extending from the heat radiating portion passing through the other hinge portion, each of the first and second circulation pipes having said part of the circulation pipe.

9. An electronic apparatus according to claim 7, wherein the second casing constitutes a display unit provided with a display panel.

10. An electronic apparatus according to claim 7, wherein said part of the circulation pipe has an odd-shaped circulation pipe having an inside diameter smaller than that of the other part of the circulation pipe.

11. An electronic apparatus according to claim 7, wherein said part of the circulation pipe has a plurality of parallel odd-shaped circulation pipes having inside and outside diameters smaller than those of the other part of the circulation pipe.

12. An electronic apparatus according to claim 11, wherein the odd-shaped circulation pipes are bonded to and formed integrally with one another.

13. An electronic apparatus according to claim 11, wherein the odd-shaped circulation pipes are formed independently of one another.

14. An electronic apparatus according to claim 7, wherein said part of the circulation pipe has an odd-shaped circulation pipe having an outside diameter larger than that of the other part of the circulation pipe.

15. An electronic apparatus according to claim 7, wherein the circulation pipe has a circular cross section, and said part of the circulation pipe has an odd-shaped circulation pipe having a substantially elliptic cross section.

16. An electronic apparatus according to claim 7, wherein said part of the circulation pipe is formed of a material different from that of the other part of the circulation pipe.

17. An electronic apparatus according to claim 7, wherein said part of the circulation pipe is formed integrally of the same material with the other part of the circulation pipe.

18. An electronic apparatus according to claim 7, wherein said other part of the circulation pipe and said part of the circulation pipe are connected by a pipe joint.

19. An electronic apparatus according to claim 7, which further comprises a protective cover which covers said part of the circulation pipe.

20. An electronic apparatus according to claim 19, wherein the protective cover is fixed to one of the first and second casings.
